(19) United States
(12) Patent Application Publication
(10) Pub. No.: US 2003/0222316 A1
(43) Pub. Date: Dec. 4, 2003

(54) Semiconductor device and method for fabricating the same

(75) Inventors: Shinji Miyagaki, Kawasaki (JP); Masaomi Yamaguchi, Kawasaki (JP); Yasuyuki Tamura, Kawasaki (JP); Yoshiaki Tanida, Kawasaki (JP); Chikako Yoshida, Kawasaki (JP); Yoshihiro Sugiyama, Kawasaki (JP); Hitoshi Tanaka, Kawasaki (JP)

Correspondence Address: ARMSTRONG, KRATZ, QUINTOS, HANSON & BROOKS, LLP, 1725 K STREET, NW, SUITE 1000, WASHINGTON, DC, 20006, US

(73) Assignee: FUJITSU LIMITED, Kawasaki (JP)

(21) Appl. No.: 10/382,886

(22) Filed: Mar. 7, 2003

(30) Foreign Application Priority Data
May 31, 2002 (JP) 2002-159148

(51) Int. Cl. H01L 29/76; H01L 29/94; H01L 31/062; H01L 31/113; H01L 31/119

(52) U.S. Cl. 257/368

(57) ABSTRACT

The semiconductor device comprises a p type silicon substrate 18, a gate insulation film 27 of a layer film of a silicon oxynitride film 25 and an aluminum oxide film 26 which are sequentially formed on the p type silicon substrate 18, and a gate electrode 28 formed on the gate insulation film 27. Accordingly, both the flat band voltage shift and the hysteresis can be depressed. Thus, MIS transistors having good device characteristics can be realized.

### CROSS-REFERENCE TO RERATED APPLICATION

This application is based upon and claims priority of Japanese Patent Application No. 2002-159148, filed on May 31, 2002, the contents being incorporated herein by reference.

### BACKGROUND OF THE INVENTION

The present invention relates to a semiconductor device and a method for fabricating the semiconductor device, more specifically a semiconductor device including a high-dielectric-constant insulation film as a gate insulation film and a method for fabricating the semiconductor device.

Conventionally, as gate insulation films of MIS (Metal-Insulator-Semiconductor) transistors, insulation films of silicon oxide film-based films, which are well compatible with silicon process, have been used. However, as semiconductor devices are more micronized, the gate insulation films have become extremely thinner, and the silicon oxide film-based gate insulation films have become unable to ensure sufficient insulation resistance. Various studies relating to gate insulation films have been made about structures and materials which can ensure desired transistor characteristics and provide sufficient insulation resistance.

In such background, the future semiconductor devices must use gate insulation films which not only can ensure desired transistor characteristics, but also can ensure sufficient insulation resistance.

Recently it is noted to use insulation films of high-dielectric-constant materials, such as Al₂O₃, ZrO₂, HfO₂, etc. as the gate insulation films of MIS transistors, which can ensure sufficient insulation resistance. The use of insulation films of high dielectric constants than silicon oxide film-based insulation films allows a film thickness of the gate insulation films for ensuring the same MIS capacitance to be large. Accordingly, such high-dielectric-constant materials are used, whereby higher insulation resistance can be ensured while the same transistor characteristics are realized.

However, when MIS transistors using insulation films of the above-described high-dielectric-constant materials are formed, the MIS transistors have disadvantages that the capacitance-voltage (C-V) characteristics have large flat band voltage shifts ΔV_{fb} and large hysteresis. Accordingly, even when MIS transistors having the gate insulation films formed of the conventional high-dielectric-constant materials are formed, it has been difficult to realize sufficient transistor characteristics.

### SUMMARY OF THE INVENTION

An object of the present invention is to provide a semiconductor device including high-dielectric-constant gate insulation films which can depress the flat band voltage shift and hysteresis, and a method for fabricating the semiconductor device.

According to one aspect of the present invention, there is provided a semiconductor device comprising: a semiconductor substrate; a gate insulation film formed on the semiconductor substrate and including an aluminum oxide film containing 0.03-3% nitrogen; and a gate electrode formed on the gate insulation film.

According to another aspect of the present invention, there is provided a semiconductor device comprising: a semiconductor substrate; a gate insulation film formed on the semiconductor substrate and including an aluminum oxide film containing nitrogen formed by using organic hydrazine as a nitrogen source; and a gate electrode formed on the gate insulation film.

According to further another aspect of the present invention, there is provided a method for fabricating a semiconductor device comprising the steps of: forming a gate insulation film including an aluminum oxide film containing 0.03-3% nitrogen on a semiconductor substrate; and forming a gate electrode on the gate insulation film.

According to further another aspect of the present invention, there is provided a method for fabricating a semiconductor device comprising the steps of: forming a gate insulation film including an aluminum oxide film containing nitrogen by using organic hydrazine as a nitrogen source; and forming a gate electrode on the gate insulation film.

As described above, the semiconductor device according to the present invention comprises a semiconductor substrate, a gate insulation film including an aluminum oxide film containing nitrogen, and a gate electrode formed on the gate insulation film, whereby both the flat band voltage shift and the hysteresis can be depressed. Accordingly, MIS transistors having good device characteristics can be realized.

### BRIEF DESCRIPTION OF THE DRAWINGS

FIG. 1 is a sectional view of the MIS capacitor used in measuring the C-V characteristics of an aluminum oxide film with nitrogen added.

FIGS. 2A, 2B, and 2C are sectional views of the MIS capacitors used in measuring C-V characteristics of the aluminum oxide films with nitrogen added, which are in the steps of the method for fabricating the MIS capacitors.

FIGS. 3A and 3B are graphs of relationships among flat band voltage shifts, hysteresis and content ratios of nitrogen in the aluminum oxide film in C-V characteristics of the aluminum oxide film with nitrogen added.

FIG. 4 is a sectional view of the semiconductor device according to one embodiment of the present invention, which shows a structure thereof.

FIGS. 5A, 5B, 5C, and 5D are sectional views of the semiconductor device according to the embodiment of the present invention in the steps of the method for fabricating the same, which explain the method (Part 1).

FIGS. 6A, 6B, and 6C are sectional views of the semiconductor device according to the embodiment of the present invention in the steps of the method for fabricating the same, which explain the method (Part 2).

FIG. 7 is a sectional view of the semiconductor device according to a modification of the present invention, which shows a structure thereof.

### DETAILED DESCRIPTION OF THE INVENTION

[Principle of the Present Invention]

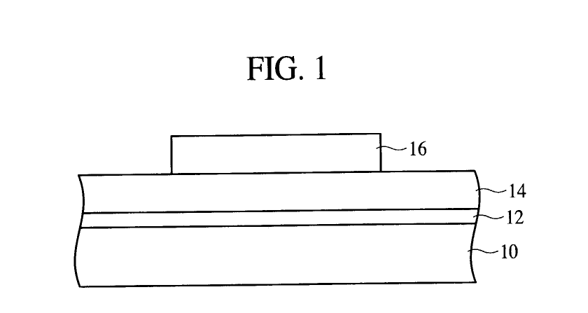

In order to realize a MIS transistor having good device characteristics, the inventors of the present invention have made earnest studies of high-dielectric-constant insulation films which are applicable to the gate insulation film. The inventors repeated the measurement of C-V characteristics of MIS capacitors including various high-dielectric-constant insulation films and found that both the flat band voltage shift and hysteresis can be depressed by adding nitrogen by a prescribed content ratio to aluminum oxide, which is one of the high-dielectric-constant materials. The measurement of the C-V characteristics of the MIS capacitors made by the inventors of the present application will be explained with reference to FIGS. 1, 2A, 2B, 3A, and 3B.

FIG. 1 is a sectional view of the MIS capacitor used in the C-V measurement. An about 1 nm-thickness chemical oxide film 12 is formed on the surface of a p type silicon substrate 10. An about 3.5 nm-thickness nitrogen-added aluminum oxide film 14 is formed on the chemical oxide film 12. A platinum electrode 16 of an bout 300 μm-diameter and a 100 nm-thickness is formed on the aluminum oxide film 14.

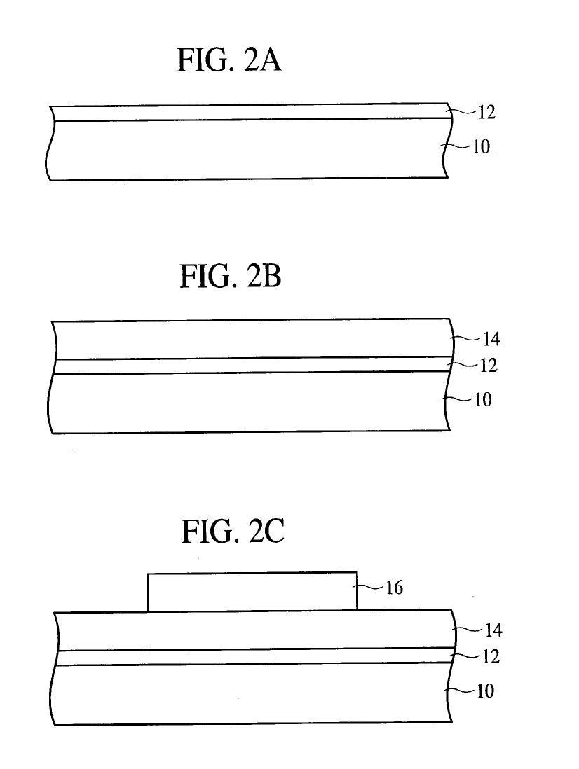

Then, the method for fabricating the above-described MIS capacitors will be explained with reference to FIG. 2A, 2B, and 2C. FIG. 2A, 2B, and 2C are sectional views of the MIS capacitors used in the C-V measurement in the steps of the method for fabricating the MIS capacitors.

First, a p type silicon substrate 10 was cleaned with a mixed liquid of sulfuric acid and hydrogen peroxide to remove organic contaminants staying on the surface. Then, the p type silicon substrate 10 was cleaned with hydrofluoric acid to remove natural oxide films formed on the surface.

Next, the p type silicon substrate was cleaned with a mixed liquid of hydrochloric acid and hydrogen peroxide. This cleaning formed the about 1 nm-thickness chemical oxide film 12 on the surface of the p type silicon substrate 10 (FIG. 2A).

Then, the aluminum oxide film 14 with nitrogen added by a prescribed content ratio was formed on the chemical oxide film 12 by MOCVD (Metal Organic Chemical Vapor Deposition) (FIG. 2B). The film forming conditions were a 500 ° C. film forming temperature and a 65 Pa film forming pressure. As source gases, a 0.05 sccm of Al(C₂H₅)₃ (triethylalminum), a 0-30 sccm of (CH₃)₂NNH₂ (1,1-dimethylhydrazine), and a 500 sccm of O₂ were fed into the film forming chamber of the film forming system in a 1500 sccm-total flow rate with N₂ as a carrier gas added to, and a period of time for forming the film is 840 seconds. The (CH₃)₂NNH₂ was fed into the chamber at the different flow rates to thereby form the aluminum oxide film 14 of different nitrogen content ratios.

Then, platinum was sputtered on the aluminum oxide film 14 with a metal mask therebetween to form the about 300 μm-diameter and about 100 μm-thickness platinum electrode 16 (FIG. 2C).

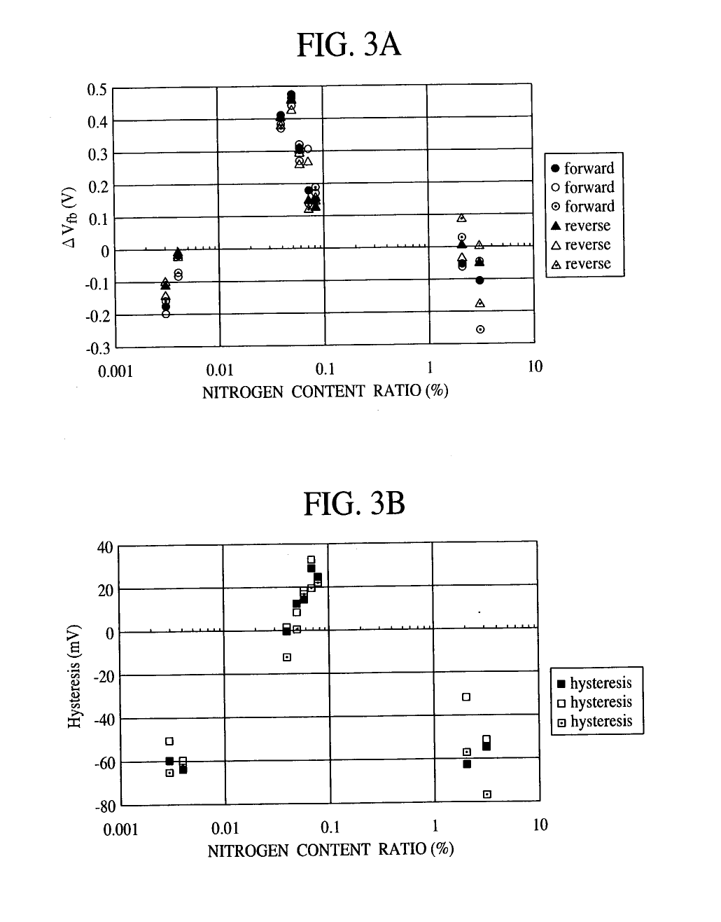

The inventors of the present invention measured C-V characteristics of the respective MIS capacitors which have been formed as described above and include the aluminum oxide films 14 of different nitrogen content ratios. As a result, relationships among content ratios of nitrogen in the aluminum oxide films 14, flat band voltage shifts ΔV_{fb} and hysteresis as shown in FIGS. 3A and 3B were obtained. FIG. 3A is a graph of the relationships between the content ratios of nitrogen in the aluminum oxide films 14 and ΔV_{fb}. FIG. 3B is a graph of the relationships between the content ratios of nitrogen in the aluminum oxide film 14 and the hysteresis. In the specification of the present application, the content ratios of nitrogen in the aluminum oxide film are represented in atomic percentage.

As evident in FIGS. 3A and 3B, in the range of 0.003-3% content ratios of nitrogen in the aluminum oxide film 14, as the nitrogen content ratio increases, both ΔV_{fb} and hysteresis increase from the negative values to the positive values and decrease from the positive values again to be the negative values. Based on the characteristics of the ΔV_{fb} and hysteresis changes for the nitrogen content ratios of the aluminum oxide film 14, a range of the nitrogen content ratio of the aluminum oxide film 14, which can depress the ΔV_{fb} and hysteresis, can be defined.

First, as for the ΔV_{fb}, as evident in FIG. 3A, in order to depress the absolute value of the ΔV_{fb} to be below 0.2 V it is effective to set a content ratio of nitrogen in the aluminum oxide film 14 to be in a 0.1-3% range. In order to depress the absolute value of the ΔV_{fb} to be below 0.1 V it is effective to set a content ratio of nitrogen in the aluminum oxide film 14 in a 0.1-2% range.

As for the hysteresis, as evident in FIG. 3B, in order to depress the absolute value of the hysteresis to be below 30 mV it is effective to set a content ratio of nitrogen in the aluminum oxide film 14 in a 0.03-2% range. Furthermore, in order to depress the absolute value of the hysteresis to be below 20 mV it is effective define a content ratio of nitrogen in the aluminum oxide film in a 0.03-1% range.

Accordingly, in order to depress the absolute value of the ΔV_{fb} to be below 0.2 V and the absolute value of the hysteresis to be below 30 mV it is effective to set a content ratio of nitrogen in the aluminum oxide film 14 in a 0.1-2% range. Furthermore, in order to depress the absolute value of the ΔV_{fb} to be below 0.1 V and the absolute value of the hysteresis to be below 20 mV it is effective to set a content ratio of nitrogen in the aluminum oxide film 14 in a 0.1-1% range.

The semiconductor device and the method for fabricating the semiconductor device according to the present invention is characterized mainly in that, based on the above-described knowledge, the gate insulation film of a MIS transistor is an insulation film including an aluminum oxide film with nitrogen added in a prescribed content ratio which can depress the ΔV_{fb} and the hysteresis. Thus, both the flat band voltage shift and the hysteresis can be depressed, whereby a MIS transistor having good device characteristics can be realized.

[An Embodiment]

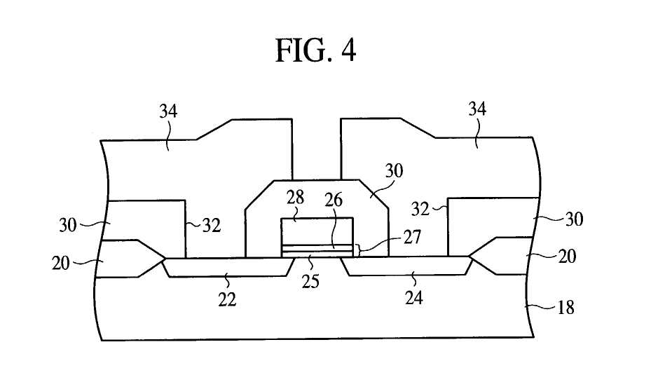

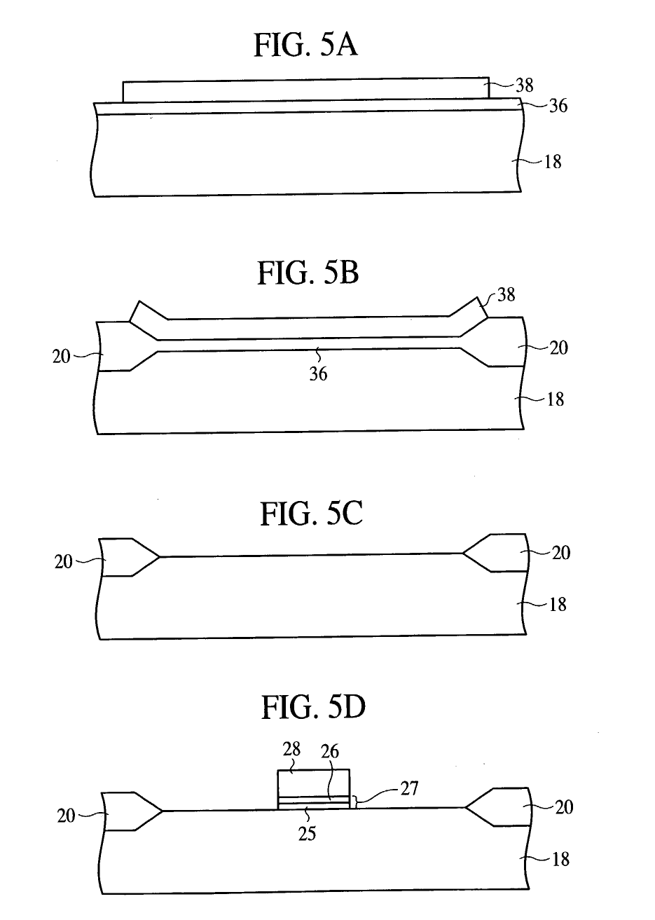

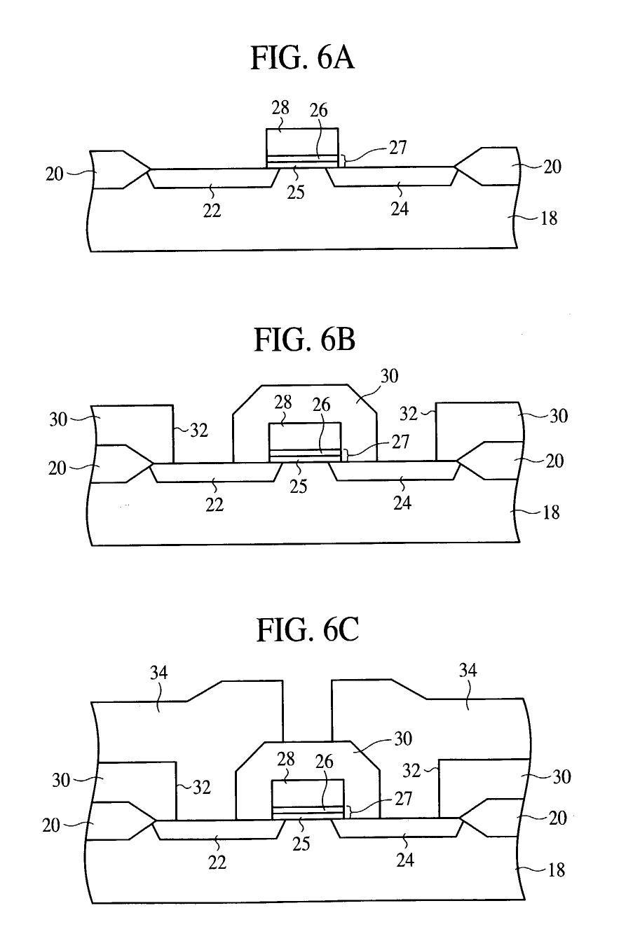

The semiconductor device and the method for fabricating the same according to one embodiment of the present invention will be explained with reference to FIGS. 4, 5A, 5B, 5C, 5D, 6A, 6B, and 6C. FIG. 4 is a sectional view of the semiconductor device according to the present embodiment, which shows the structure thereof. FIGS. 5A, 5B, 5C, 5D, 6A, 6B, and 6C are sectional views of the semiconductor device according to the present embodiment in the steps of the method for fabricating the same, which explain the method.

The semiconductor device according to the present embodiment and the method for fabricating the same use an aluminum oxide film with nitrogen added in a prescribed content ratio which has been explained in the principle of the present invention as the gate insulation film of the MIS capacitor.

First, the semiconductor device according to the present embodiment will be explained with reference to FIG. 4.

An element isolation film 20 of a silicon oxide film is formed on the surface of a p type silicon substrate 18. A source/drain diffused layer 22, 24 is formed in an element region defined by the element isolation film 20. A gate insulation film 27 of the layer film of an about 1 nm-thickness silicon oxynitride film 25 and an about 3.5 nm-thickness aluminum oxide film 26 containing nitrogen is formed on the p type silicon substrate 18 between the source/drain diffused layers 22, 24. A gate electrode 28 is a polysilicon film is formed on the gate insulation film 27. Thus, a MIS transistor including the gate electrode 28 and the source/drain diffused layer 22, 24 is formed.

An inter-layer insulation film 30 of an about 200 nm-thickness silicon oxide film is formed on the p type silicon substrate 18 with the MIS transistor formed on. Contact holes 32 are opened in the inter-layer insulation film 30 down to the source/drain diffused layers 22, 24. Metal interconnection layers 34 are buried in the contact holes 32, electrically connected to the source/drain diffused layers 22, 24.

The semiconductor device according to the present embodiment is characterized mainly by the gate insulation film 27 including the aluminum oxide film 26 with nitrogen added in a prescribed content ratio. For example, a nitrogen content ratio in the aliminum oxide film 26 is set to be within 0.1-2%, whereby the absolute value of the flat band voltage shift can be depressed to be below 0.2 V, and the absolute value of the hysteresis can be depressed to be below 30 mV. The nitrogen content ratio is set to be within 0.1-1%, whereby the absolute value of the flat band voltage shift can be depressed to be below 0.1 V, and the absolute value of the hysteresis can be depressed to be below 20 mV. Thus, a MIS transistor having good device characteristics can be realized.

Next, the method for fabricating the semiconductor device according to the present embodiment will be explained with reference to FIGS. 5A, 5B, 5C, 5D, 6A, 6B, 6C, and 6D.

First, a p type silicon substrate 18 is thermally processed to form an about 5 nm-thickness silicon oxide film 36 on the surface. Then, an about 100 nm-thickness silicon nitride film 38 is formed on the p type silicon substrate 18 with the silicon oxide film 36 formed on by, e.g., CVD (Chemical Vapor Deposition).

Then, the silicon nitride film 38 is patterned by lithography and etching to leave the silicon nitride film 38 in a region of the p type silicon substrate 18, which is to be the element region (FIG. 5A).

Next, the p type silicon substrate 18 with the patterned silicon nitride film 38 formed on is oxidized to grow in the region of the p type silicon substrate 18 where the silicon nitride film 38 is not formed the element isolation film 20 of the silicon oxide film of an about 250 nm-thickness for defining the element region (FIG. 5B).

Next, the silicon nitride film 38 and the silicon oxide film 36 are etched off (FIG. 5C).

Then, a silicon oxynitride film 25 is formed on the entire surface.

Next, an about 3.5 nm-thickness aluminum oxide film 26 with nitrogen added in a prescribed content ratio is formed on the entire surface by, e.g., MOCVD. As the film forming conditions, for example, Al(C₂H₅)₃ (triethylalminum) of a 0.05 sccm flow rate, (CH₃)₂NNH₂ (1,1-dimethylhydrazine) of a 1-20 sccm flow rate, O₂ of a 500 sccm flow rate and N₂ gas as a carrier gas are fed at a 1500 sccm total flow rate into the film forming chamber of the film forming system at a 500 ° C. film forming temperature and a 65 Pa film forming pressure. Under such a condition, the film formation is performed for 840 second.

Next, an about 150 nm-thickness polysilicon film which is to be the gate electrode 28 is formed on the aluminum oxide film 26 by, e.g., CVD.

Next, the polysilicon film, the aluminum oxide film 26 and the silicon oxynitride film 25 are sequentially patterned by, e.g., RIE (Reactive Ion Etching). Thus, in the element region of the p type silicon substrate 18, the gate insulation film 27 of the layer film of the silicon oxynitride film 25 and the aluminum oxide film 26 is formed, and the gate electrode 28 of the MIS transistor is formed (FIG. 5D).

Next, with the gate electrode 28 as a mask, ion implantation is performed to form the source/drain diffused layers 22, 24 in the p type silicon substrate 18 on both sides of the gate electrode 28 (FIG. 6A). For example, P⁺ ions are implanted at 15 keV and a 4 ×10¹⁵ cm⁻² dose.

Then, after an insulation film of, e.g., a silicon nitride film or others is formed, the insulation film is anisotropically etched by RIE to form a sidewall insulation film (not shown) on the side wall of the gate electrode 28.

Next, the inter-layer insulation film 30 of an about 200 nm-thickness silicon oxide film is formed on the entire surface by, e.g., CVD. Then, the contact holes 32 are formed in the inter-layer insulation film 30 down to the source/drain diffused layers 22, 24 by lithography and etching (FIG. 6B).

The metal interconnection layers 34 are formed on the inter-layer insulation film 30, electrically connected to the source/drain diffused layers 22, 24 (FIG. 6C).

Thus, the semiconductor device according to the present embodiment is fabricated.

As described above, the gate insulation film 27 including the aluminum oxide film 26 with nitrogen added in a prescribed content ratio is formed, whereby both the flat band voltage shift and the hysteresis can be depressed to be small. Accordingly, a MIS transistor of good device characteristics can be realized.

[Modifications]

The present invention is not limited to the above-described embodiment and can cover other various modifications.

For example, in the above-described embodiment, the nitrogen source for forming the aluminum oxide film 26 containing nitrogen of the gate insulation film 27 is (CH₃)₂NNH₂, but the nitrogen source is not limited to (CH₃)₂NNH₂. For example, other organic hydrazine, such as CH₃NHNHCH₃ (1,2-dimethylhydrazine), CH₃NHNH₂ (methylhydrazine) or others, can be used as the nitrogen source. Dinitrogen monoxide, nitrogen monoxide, ammonia or others other than organic hydrazine may be used as a nitrogen source.

In the above-described embodiment, the silicon oxynitride film 25 and the aluminum oxide film 26 containing nitrogen are sequentially formed on a p type silicon substrate 18, and the layer film of these films is the gate insulation film 27, but the gate insulation film 27 is not essentially the layer film. For example, layer films of other insulation films, such as thermal oxide film, a chemical oxide film, etc., formed on the surface of the p type silicon substrate 18, and the aluminum oxide film 26 containing nitrogen may be used as the gate insulation film 27. The thermal oxide film and the chemical oxide film can be formed on the p type silicon substrate 18 respectively by subjecting the p type silicon substrate 18 to thermal processing and by processing the p type silicon substrate 18 with an oxidizing chemical liquid, e.g., a mixed liquid of hydrochloric acid and hydrogen peroxide or others.

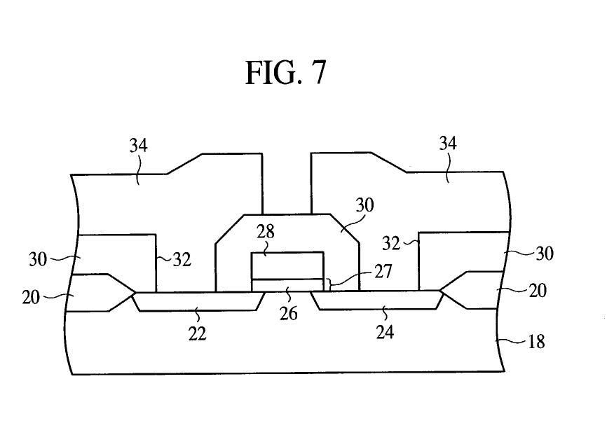

As shown in FIG. 7, it is possible that the aluminum oxide film 26 containing nitrogen is formed directly on the p type silicon substrate 18, and the formed aluminum oxide film 26 is singly used as the gate insulation film 27.

In the above-described embodiment, the gate electrode 28 is formed of a polysilicon film, but the structure of the gate electrode 28 is not essentially limited to this structure. For example, it is possible that a metal silicide film is formed on a polysilicon film to form the gate electrode 28 of the polycide structure. It is possible that in place of the polysilicon film, a metal film, as of titanium nitride, tantalum nitride or others is formed on the gate insulation film 27 to thereby form the gate electrode 28 of the metal gate.

What is claimed is:

1. A semiconductor device comprising:
a semiconductor substrate;
a gate insulation film formed on the semiconductor substrate and including an aluminum oxide film containing 0.03-3% nitrogen; and
a gate electrode formed on the gate insulation film.

2. A semiconductor device according to claim 1, wherein
the aluminum oxide film contains 0.1-2% nitrogen.

3. A semiconductor device according to claim 2, wherein
the aluminum oxide film contains 0.1-1% nitrogen.

4. A semiconductor device comprising:
a semiconductor substrate;
a gate insulation film formed on the semiconductor substrate and including an aluminum oxide film containing nitrogen formed by using organic hydrazine as a nitrogen source; and
a gate electrode formed on the gate insulation film.

5. A semiconductor device according to claim 1, wherein
the gate insulation film comprises a layer film of at least one layer of an insulation film formed on the semiconductor substrate and the aluminum oxide film formed on the insulation film.

6. A semiconductor device according to claim 5, wherein
the insulation film is a thermal oxide film or a chemical oxide film.

7. A semiconductor device according to claim 5, wherein
the insulation film is a silicon oxynitride film.

8. A method for fabricating a semiconductor device comprising the steps of:
forming a gate insulation film including an aluminum oxide film containing 0.03-3% nitrogen on a semiconductor substrate; and
forming a gate electrode on the gate insulation film.

9. A method for fabricating a semiconductor device according to claim 8, wherein
in the step of forming gate insulation film, the aluminum oxide film containing 0.1-2% nitrogen is formed.

10. A method for fabricating a semiconductor device according to claim 9, wherein
in the step of forming gate insulation film, the aluminum oxide film containing 0.1-1% nitrogen is formed.

11. A method for fabricating a semiconductor device according to claim 8, wherein
in the step of forming the aluminum oxide film, organic hydrazine is used as a nitrogen source for adding nitrogen to the aluminum oxide film.

12. A method for fabricating a semiconductor device comprising the steps of:
forming a gate insulation film including an aluminum oxide film containing nitrogen by using organic hydrazine as a nitrogen source; and
forming a gate electrode on the gate insulation film.

13. A method for fabricating a semiconductor device according to claim 11, wherein
in the step of forming the aluminum oxide film, (CH₃)₂NNH₂, CH₃NHNHCH₃ or CH₃NHNH₂ is used as the organic hydrazine.

14. A method for fabricating a semiconductor device according to claim 12, wherein
in the step of forming the aluminum oxide film, (CH₃)₂NNH₂, CH₃NHNHCH₃ or CH₃NHNH₂ is used as the organic hydrazine.

15. A method for fabricating a semiconductor device according to claim 8, wherein
in the step of forming the aluminum oxide film, ammonia, dinitrogen monoxide or nitrogen monoxide is used as a nitrogen source for adding nitrogen to the aluminum oxide film.

16. A method for fabricating a semiconductor device according to claim 8, wherein
the step of forming the gate insulation film includes the step of forming at least one layer of an insulation film on the semiconductor substrate, and the step of forming the aluminum oxide film on the insulation film.

17. A method for fabricating a semiconductor device according to claims 12, wherein
the step of forming the gate insulation film includes the step of forming at least one layer of an insulation film on the semiconductor substrate, and the step of forming the aluminum oxide film on the insulation film.

18. A method for fabricating a semiconductor device according to claim 16, wherein
in the step of forming the insulation film, the semiconductor substrate is thermally processed to form a thermal oxide film as the insulation film on the surface of the semiconductor substrate.

19. A method for fabricating a semiconductor device according to claim 16, wherein
in the step of forming the insulation film, the semiconductor substrate is processed with an oxidizing chemical liquid to form a chemical oxide film as the insulation film on the surface of the semiconductor substrate.

20. A method for fabricating a semiconductor device according to claim 16, wherein
in the step of forming the insulation film, a silicon oxynitride film is formed as the insulation film.
